(19) United States
(12) Patent Application Publication
(10) Pub. No.: US 2006/0049399 A1
(43) Pub. Date: Mar. 9, 2006

(54) Germanium-on-insulator fabrication utilizing wafer bonding

(76) Inventors: Ryan Lei, Hillsboro, OR (US); Mohamad Shaheen, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/245,778

(22) Filed: Oct. 6, 2005

Related U.S. Application Data
(62) Division of application No. 10/672,033, filed on Sep. 25, 2003.

(51) Int. Cl. H01L 29/08

(52) U.S. Cl. 257/40

(57) ABSTRACT

Methods of forming a germanium on insulator structure and its associated structures are described. Those methods comprise forming an epitaxial germanium layer on a sacrificial silicon layer, removing a portion of the epitaxial germanium layer, activating the epitaxial germanium layer and an oxide layer disposed on a silicon substrate in an oxygen plasma, and bonding the epitaxial germanium layer to the oxide layer to form a germanium on insulator structure.

### FIELD OF THE INVENTION

The present invention relates to the field of microelectronic processing, and more particularly to methods of forming a germanium on insulator structure and structures formed thereby.

### BACKGROUND OF THE INVENTION

Microelectronic technology will face major roadblocks in the development of advanced transistors structures as device scaling continues to decrease. Building advanced microelectronic devices on germanium substrates has become increasingly more attractive due to the very high mobility of both electrons and holes in the germanium substrate. Germanium substrates can potentially provide improved performance as compared to advanced strained silicon layers, for example. Devices fabricated on germanium on insulator (GOI) substrates (e.g., a substrate that may comprise a germanium layer disposed on an insulator that is disposed on a substrate, such as silicon) are further enhanced due to the leakage reduction potential of the buried insulating layer that is typically employed in a GOI substrate.

However, there are many obstacles associated with GOI fabrication, especially when using wafers that are 300 mm in scale. For example, epitaxial growth of germanium directly onto an insulator layer (e.g. silicon dioxide) yields an amorphous germanium layer that is substantially ineffective for microelectronic devices. In addition, the mismatch between the crystal lattices of the germanium and oxide layers may inhibit direct epitaxial germanium growth on an oxide layer due to unacceptable levels of induced stress. Furthermore, even though GOI substrates can be fabricated by bonding an oxide substrate such as an oxide wafer, for example, to a germanium wafer, germanium wafers are scarce and expensive. They are also heavy and fragile compared to silicon wafers.

Therefore, there is a need for improved methods of germanium on insulator fabrication. The present invention provides such methods and their associated structures.

### BRIEF DESCRIPTION OF THE DRAWINGS

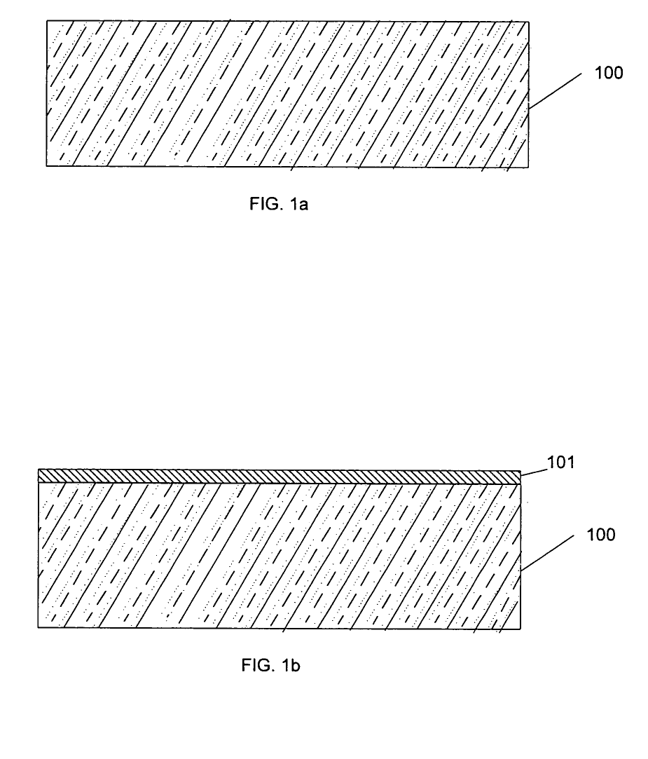

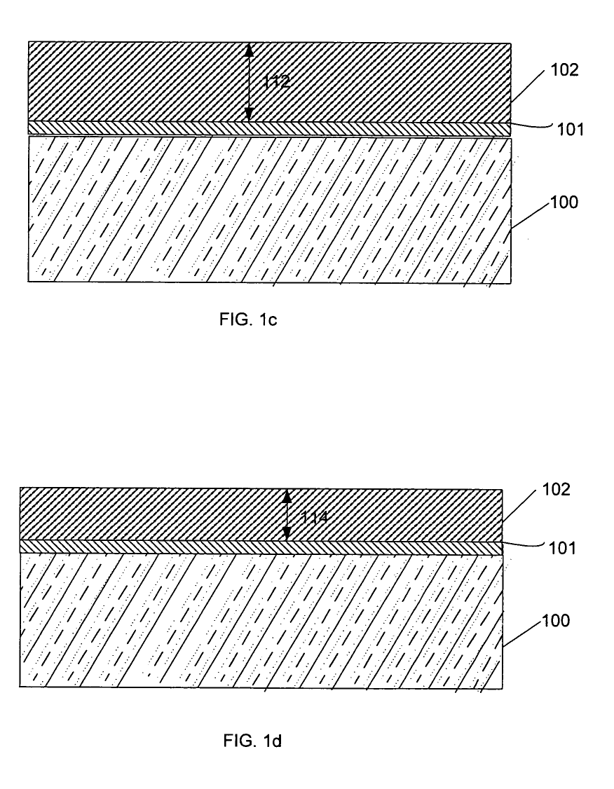

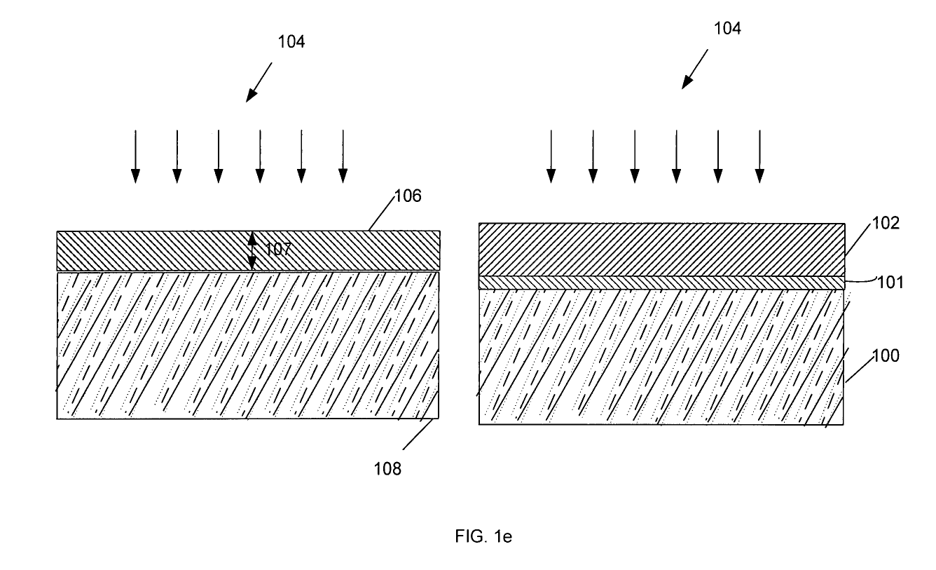

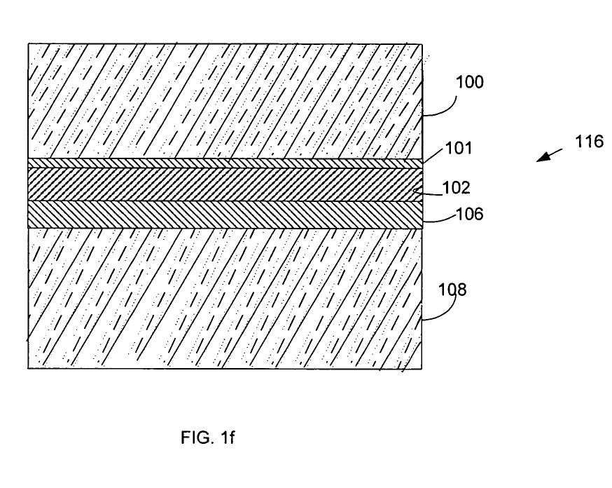

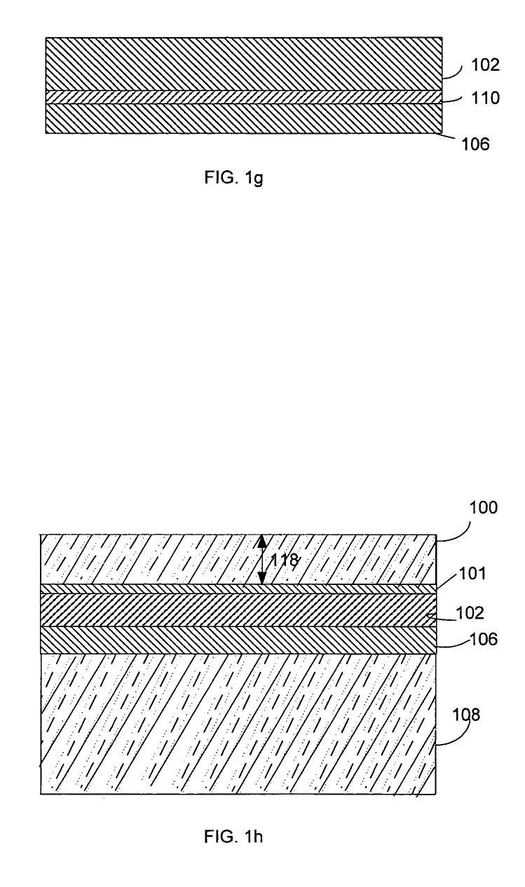

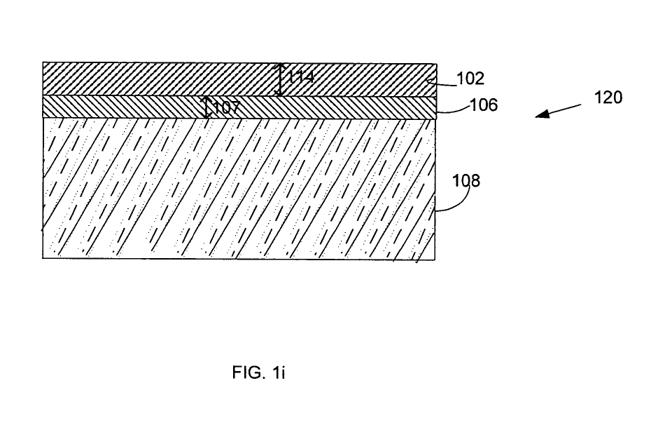

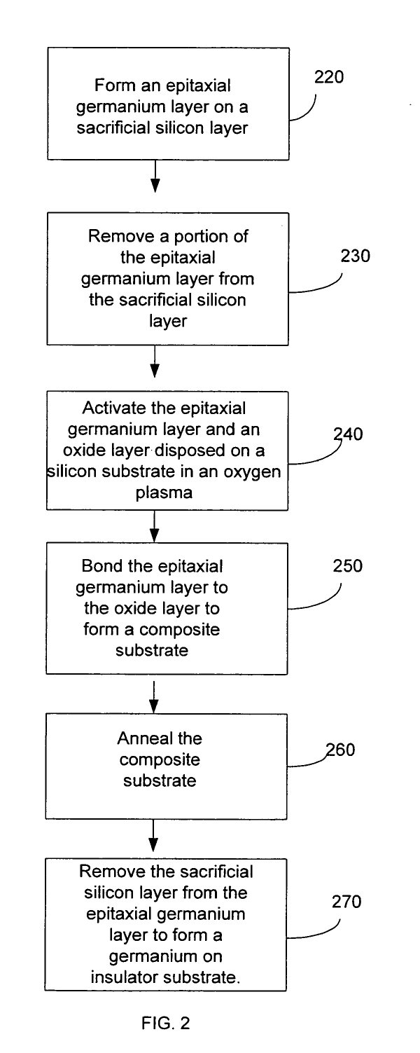

While the specification concludes with claims particularly pointing out and distinctly claiming that which is regarded as the present invention, the advantages of this invention can be more readily ascertained from the following description of the invention when read in conjunction with the accompanying drawings in which: FIGS. 1a-1i represent cross-sections of structures that may be formed when carrying out an embodiment of the method of the present invention. FIGS. 2 represents a flowchart of a method according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods of forming a germanium on insulator structure and its associated structures are described. Those methods comprise forming an epitaxial germanium layer on a sacrificial silicon layer, removing a portion of the epitaxial germanium layer, activating the epitaxial germanium layer and an oxide layer disposed on a silicon substrate in an oxygen plasma, and bonding the epitaxial germanium layer to the oxide layer to form a germanium on insulator structure.

FIGS. 1a-1i illustrate an embodiment of a method of fabricating a germanium on insulator structure according to the present invention. FIG. 1a illustrates a portion of a sacrificial silicon layer 100 that may comprise a silicon substrate, such as a silicon wafer, a silicon containing substrate, a silicon substrate comprising an oxide layer, such as a silicon dioxide layer, or a silicon-on-insulator (SOI) substrate. The sacrificial silicon layer 100 may be monocrystalline, polycrystalline, or bulk silicon.

A buffer layer 101 may be disposed on the sacrificial silicon layer 100 (FIG. 1b). The buffer layer 101 may comprise silicon germanium, and may be formed by utilizing an epitaxial process, for example, or other such methods used to form a silicon germanium alloy as are known in the art. The buffer layer 101 may be formed by using a grading technique, as is well known in the art, in which the buffer layer 101 is formed by sequentially increasing the percentage of germanium in the buffer layer 101 as the buffer layer 101 forms. The percentage of germanium in the buffer layer 101 may be increased from about 10% to about 100%, for example. The thickness of the buffer layer 101 is preferably at least 1 micron to provide for dislocation reduction in an epitaxial germanium layer 102 subsequently deposited on the buffer layer 101.

The buffer layer 101 enables an epitaxial germanium layer 102 (FIG. 1c) to be epitaxially formed on the buffer layer 101 that may comprise low defects per centimeter squared, since the buffer layer 101 reduces the stress between the sacrificial silicon layer 100 and the epitaxial germanium layer 102 caused by the lattice mismatch between the epitaxial germanium layer 102 and the sacrificial silicon layer 100.

The epitaxial germanium layer 102 may be formed by utilizing conventional methods, suitable for the deposition of epitaxial germanium films such as by utilizing a chemical vapor deposition (CVD) or an epitaxial process, as previously described above. The deposition process may include such process gases as SiH₂Cl₂ and GeH₄, or other suitable process gases. The process temperature may be in a range from about 500 to 750 degrees Celsius, but may vary depending on the process equipment and the particular application. It will be understood by those skilled in the art that while a few examples of the process parameters may be included herein, the epitaxial germanium layer 102 may be formed by other methods or processes that form an epitaxial germanium alloy. A first thickness 112 of the epitaxial germanium layer 102 may be from about 1600 angstroms to about 2400 angstroms, and may be about 2,000 angstroms, but the thickness of the epitaxial germanium layer 102 may also vary depending on the application.

The epitaxial germanium layer 102 surface may be polished to remove a predetermined amount, or portion, of the epitaxial germanium layer 102 (FIG. 1d). This polishing step also serves to smooth the epitaxial germanum layer 102 surface. After the cleaning process, the epitaxial germanium layer 102 may be polished to remove a predetermined amount, or portion, of the epitaxial germanium layer 102 (FIG. 1d). A chemical mechanical polishing (CMP) technique (as is well known in the art) may preferably be utilized, in which the predetermined portion of the epitaxial germanium layer 102 may be removed in order to achieve a targeted second thickness 114 of the epitaxial germanium layer 102. The second thickness 114 of the epitaxial germanium layer 102 may depend on the particular application, but in this embodiment may comprise about 300 angstroms to about 2000 angstroms, and may preferably be about 500 angstroms. Removal of a predetermined portion of the epitaxial germanium layer 102 allows for greater process control of the thickness of the epitaxial germanium layer 102.

The removal process of the epitaxial germanium layer 102 may preferably comprise a removal rate for the epitaxial germanium layer 102 of about 50 angstroms per minute or less. It will be understood by those in the art that the removal rate may vary depending on the particular application. The removal of the predetermined amount of the epitaxial germanium layer provides a smooth surface (i.e., less than about 5 angstroms root mean squared (RMS) as measured using a profilometer, for example) on the surface of the epitaxial germanium layer 102.

After a predetermined portion of the epitaxial germanium layer 102 has been removed, both the epitaxial germanium layer 102 and an oxide layer 106 that is disposed on a silicon substrate 108, are exposed to an oxygen plasma 104 (FIG. 1e). It will be understood by those skilled in the art that both the oxide layer 106 and the epitaxial germanium layer 102 may be activated in the same equipment, or process step, or they may be activated in the oxygen plasma 104 in separate process steps and/or equipment. The thickness 107 of the oxide layer 106 may be targeted for specific thickness depending upon the particular application. By illustration and not limitation, the thickness 107 of the oxide layer 106 may be from about 500 angstroms to about 6000 angstroms, and may preferably be about 1,000 angstroms.

The oxygen plasma 104 activates the surface of the oxide layer 106 and the epitaxial germanium layer 102 by bombarding the epitaxial germanium layer 102 and the oxide layer 106 with oxygen ions so that a clean surface may be formed on both of the layers so that they may be bonded together in a subsequent process step. The oxygen plasma 104 may also promote the formation of dangling bonds, such as dangling oxygen or silicon bonds, which may further promote the formation of a germanium oxide interface 110 (see FIG. 1g, which depicts the germanium oxide interface 110 disposed between a portion of the oxide layer 106 and the epitaxial germanium layer 102). The germanium oxide interface 110 may be formed during a subsequent bonding process, to be described more fully herein.

Referring back to FIG. 1f of the current embodiment, the epitaxial germanium layer 102 and the oxide layer 106 may be directly bonded to each other. (FIG. 1f). Upon bonding the epitaxial germanium layer 102 to the oxide layer 106, a composite substrate 116 may be formed that comprises the sacrificial silicon layer 100 disposed on the buffer layer 101, the buffer layer 101 disposed on the epitaxial germanium layer 102, the epitaxial germanium layer 102 disposed on the oxide layer 106, and the oxide layer 106 disposed on the silicon substrate 108. The germanium oxide interface 110 (shown in FIG. 1g) may be disposed between the epitaxial germanium layer 102 and the oxide layer 106. The germanium oxide interface 110 may be about 100 angstroms or less in thickness.

The bonding of the epitaxial germanium layer 102 and the oxide layer 106 may utilizing a bonding process that is well known in the art. By illustration and not limitation, the epitaxial germanium layer 102 and the oxide layer 106 may be placed in direct contact to each other in a bonding chamber. The bonding temperature may be from about 22 degrees Celsius to about 600 degrees Celsius. The bonding chamber may be maintained in a pressure ranging from atmospheric to 1 Torr or below, and a local downward force may be applied to the composite substrate 116, which facilitates the bonding between the epitaxial germanium layer 102 and the oxide layer 106. The local force may be from about 3 Newtons to about 4,000 Newtons. Bonding an epitaxial germanium layer, such as the epitaxial germanium layer 102, to an oxide layer, such as the oxide layer 106, results in a lower lattice mismatch than as between an oxide layer bonded a crystalline germanium layer, as is currently performed in the prior art.

After the composite wafer 116 is formed and the epitaxial germanium layer 102 is bonded to the oxide layer 106, the composite substrate 116 may be annealed at a temperature between about 200 degrees to about 500 degrees Celsius, for a time period from about 10 hours to about 50 hours. The annealing process may remove and diffuse any moisture trapped at the germanium oxide interface 110. In one embodiment, the annealing process takes place in the same bonding chamber that is used for the bonding process previously described herein. In a preferred embodiment, the annealing temperature is obtained by ramping the temperature while the composite substrate 116 resides in the bonding chamber. In this embodiment, the ramping rate for the annealing temperature may be about 1° C./minute. The temperature may be ramped from about room temperature (e.g., 23° C.) to an annealing temperature of about 100° C., which may take about 77 minutes. The chamber may then be maintained or held at about 100° C. for about 20 minutes. The composite wafer 116 may then be cooled by allowing the bonding chamber to cool down at a rate of about 1° C./minute. The low rate of ramping up and ramping down the temperature of the bonding chamber prevents the cracking of the composite substrate 116, while allowing the strengthening of the germanium oxide interface 110 of the composite substrate 116.

After the composite substrate 116 is annealed, a predetermined amount, or portion, of the sacrificial silicon layer 100 may be removed (FIG. 1h). The removal process may utilize a grinding technique, as is well known in the art. In the current embodiment, the sacrificial silicon substrate 100, which may comprise a silicon wafer, may be ground to a predetermined thickness 118. the predetermined thickness may be about 25 mils, but will vary depending upon the particular application. The grinding process parameters may be include first a rough surface grind using 600 grit diamond wheel followed by a fine surface grind using 2000 grit diamond wheel.

After the sacrificial silicon layer 100 is removed, or ground to a predetermined thickness 118, the remaining portion of the sacrificial silicon layer 100 may be etched utilizing a wet etch process (FIG. 1i). The wet etch process parameters may include utilizing a TMAH silicon etch solution, well known in the arts.

Thus, a germanium on insulator structure 120 may be formed according to the method of the current embodiment of the present invention. It will be understood by those skilled in the art that the epitaxial germanium layer 102 second thickness 114 of the germanium on insulator structure 120 may be further thinned using an additional previously mentioned CMP process. The germanium on insulator structure 120 of the present invention allows for the targeting of the epitaxial germanium layer 102 second thickness 114, as well as for the targeting of a buried oxide layer thickness, such as the oxide layer 106 thickness 107. The germanium on insulator structure 120 improves the speed and lowers the cost of a device fabricated according to the methods of the present invention.

FIG. 2 depicts a flow chart of an embodiment of the present invention. At step 220, an epitaxial germanium layer may be formed on a sacrificial silicon layer. At step 230, a portion of the epitaxial germanium layer may be removed from the sacrificial silicon layer. At step 240, the epitaxial germanium layer and an oxide layer disposed on a silicon substrate may be activated in an oxygen plasma. At step 250, the epitaxial germanium layer may be bonded to the oxide layer to form a composite substrate. At step 260, the composite substrate may be annealed, and at step 270, the sacrificial silicon layer may be removed from the epitaxial germanium layer to form a germanium on insulator substrate.

As described above, the present invention provides methods and associated structures of forming a germanium on insulator structure. The methods and structures of the present invention enable the fabrication of a large diameter germanium on insulator structure, such as a 300 mm germanium on insulator wafer, since the germanium layer of the germanium on insulator structure is epitaxially grown and therefore is not as brittle as a crystalline germanium on insulator structure of the prior art, and is furthermore less costly to fabricate.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that the fabrication of a multiple layer structure atop a substrate, such as a silicon substrate, to manufacture a microelectronic device is well known in the art. Therefore, it is appreciated that the Figures provided herein illustrate only portions of an exemplary microelectronic device that pertains to the practice of the present invention. Thus the present invention is not limited to the structures described herein.

1-19. (canceled)

20. A germanium on insulator structure comprising:
an epitaxial germanium layer comprising a diameter equal to or larger than about 300 mm disposed on an oxide layer that is disposed on a silicon substrate, wherein the silicon substrate is about 300 mm in diameter.

21. The structure of claim 20 further comprising a germanium oxide interface between the epitaxial germanium layer and the oxide layer that is less than about 100 angstroms in thickness.

22. The structure of claim 20 wherein the oxide layer is about 1,000 angstroms thick.

23. The structure of claim 20 wherein the epitaxial germanium layer is about 1,500 angstroms thick.
